(19) United States
(12) Patent Application Publication
(10) Pub. No.: US 2024/0040028 A1
(43) Pub. Date: Feb. 1, 2024

(54) Wireless Controller

(71) Applicant: INNO INSTRUMENT (CHINA) INC., Weihai City (CN)

(72) Inventor: Yangri Zhao, Weihai City (CN)

(73) Assignee: INNO INSTRUMENT (CHINA) INC., Weihai City (CN)

(21) Appl. No.: 18/487,117

(22) Filed: Oct. 15, 2023

(30) Foreign Application Priority Data
Aug. 23, 2023 (CN) CN202311062288.0

(51) Int. Cl. H04M 1/72409; H04M 1/72457; H04M 1/72406; G06F 8/30; G05D 1/00; G05D 1/02

(52) U.S. Cl. CPC H04M 1/72409; H04M 1/72457; H04M 1/72406; G06F 8/30; G05D 1/0016; G05D 1/0206; G05D 1/0044; H04M 2250/10

(57) ABSTRACT

Disclosed is a wireless controller, including a remote control body, which includes a processing mechanism disposed at the top of the remote control body, a mounting mechanism disposed on an outer side of the processing mechanism, and a protective mechanism disposed on the bottom of the remote control body; and the processing mechanism includes a protective casing disposed on an outer side of remote control body. For the wireless controller, the arrangement of the processing mechanism, the protective mechanism and the connection assembly can effectively help the mounting and fixation of the control-type electrical components of the remote control body, and at the same time, upon completion of the mounting, the dual-screen design adopted by the display screen can effectively improve the functionality of the device during use, and make the use more convenient, allowing the user to directly observe the device and the operation of the device during user.

### TECHNICAL FIELD

The present disclosure relates to the technical field of electric surfboard control, and in particular to a wireless controller.

### BACKGROUND

An electric surfboard is a kind of surfboard powered by a lithium battery, and a built-in lithium battery can provide a motor of the electric surfboard with kinetic energy for about 1 hour. The surfboard was initially designed for recreational use, however, it was soon favored by rescue teams and lifeguards because of its low cost as a lightweight watercraft, being more convenient than boats and jet boards, and capable of being used for rescue purpose. When in use, the electric surfboard needs to be controlled by a controller, however, existing wireless controllers are unable to realize split-screen display during the use, and do not have mounting mechanism for action cameras, furthermore, they have no GPS positioning function and are incapable of displaying movement trajectories on a mobile terminal. As a result, the overall functionality of a device in use is poor, unable to meet the user's needs at present, causing inconvenience to the users.

### SUMMARY

The objective of this section is to summarize some aspects of the embodiments of the present disclosure and to briefly introduce some preferred embodiments. Some simplifications or omissions may be made in this section as well as in the abstract and title of the present disclosure in order to avoid obscuring the purposes of this section, the abstract, and the title. In addition, these simplifications or omission should not be intended to limit the scope of the present disclosure.

In view of the above problem or the prior art has the problem that the split-screen display cannot be performed during use, and there is not a mounting structure for the action camera.

In order to achieve the above objective, the present disclosure provides the following technical solution:
a wireless controller, including:
a remote control body, including a processing mechanism disposed at the top of the remote control body, a mounting mechanism disposed on an outer side of the processing mechanism, and a protective mechanism disposed on the bottom of the remote control body.

As a further solution of the present disclosure, the processing mechanism includes a protective casing disposed on an outer side of remote control body, an encoder disposed on an inner side of the protective casing, a processing unit disposed on the surface of the encoder, a connecting member disposed on an outer side of the encoder, a locking member disposed on an outer side of the connecting member, a fixed shell disposed on an outer side of the protective casing, and a display screen disposed on an outer side of the processing unit.

As a further solution of the present disclosure, the dual-screen structure is arranged inside the display screen, dual screens are electrically connected parts capable of being used in conjunction with each other, and the connecting member, the protective casing, the fixed shell, and the locking member are threaded parts capable of being used in conjunction with one another.

As a further solution of the present disclosure, the mounting mechanism includes a protective member disposed on the outer side of the remote control body, a magnetic portion disposed on the inner cavity of the protective member, a control trigger disposed on an outer side of the magnetic portion, a mounting groove formed on an the outer side of the remote control body, and a mounting position disposed inside the mounting groove.

As a further solution of the present disclosure, the protective mechanism includes a handle disposed at the bottom of the remote control body, a waterproof sleeve disposed onto the surface of the handle, and a connection assembly disposed on an outer side of the handle.

As a further solution of the present disclosure, the connection assembly further includes a sealing member disposed on an outer side of the handle, a clamping plate disposed on one side of the sealing member, and a connection block disposed inside the sealing member.

In view of the above problem or the prior art has the problem that the existing wireless controllers have no GPS positioning function and are incapable of displaying movement trajectories on a mobile terminal.

In order to solve the above technical problem, the present disclosure provides the following technical solution:
a wireless controller positioning system, and:
a signal receiver, an output end of the signal receiver is electrically connected to a module, an input end of the remote control body is electrically connected to a power supply module and a microprocessor, respectively, an output end of the module is in communication connection with a cell phone development tool, an input end of the cell phone development tool is in communication connection with a map module, and an output end of the cell phone development tool is electrically connected to a data storage and processing module.

As a further solution of the present disclosure, an output end of the data storage and processing module is electrically connected to an input end of the microprocessor, and an output end of the remote control body is electrically connected to an input end of the module.

As a further solution of the present disclosure, the cell phone development tool contains an initialization module, an acquisition data module, a storage data module, a trajectory drawing module, and a real-time update trajectory module.

As a further solution of the present disclosure, the cell phone development tool needs to acquire GPS data when acquiring the movement trajectories:
including the initialization module;
reading the location information provided by the module;
storing the acquired location information; and
waiting for a certain period of time and continuing the next cycle;
drawing the trajectory:
creating a map view using a map;
looping through the stored location information;
plotting the current location point on a map, or when there is a previous location point, drawing a line segment connecting the current location point and the previous location point on the map;
clearing the previously plotted trajectory on the map after acquiring the new location information;
updating a trajectory on the map and redrawing the trajectory according to the new location information; and
iterating through the above steps to achieve the effect of real-time updating.

A wireless controller, its use method is as follows:

S1. the user uses the processing mechanism to mount and fix the protective casing, the encoder, the processing unit, the fixed shell, and the display screen through the connecting member and the locking member, and upon completion of the mounting, the user mounts the control trigger by using the protective member and the magnetic portion provided inside the mounting mechanism, and the user can then selectively mount the action camera through the mounting groove and the mounting position;

S2. upon completion of mounting the processing mechanism, the user can mount and fix the signal receiver through the sealing member, the clamping plate, and the connecting block inside the connection assembly, and the user can then put the waterproof sleeve onto the surface of the handle, and after then, the user can take the device and electrically control the surfboard in the process of surfing by holding the handle;

S3. power is provided to the remote control body through the power supply module during control. During the use of the remote control body, wireless signals needed by the device and the system are received by the signal receiver, geographic location information of the device is acquired through the module upon receipt of the wireless signals, the cell phone development tool is used in conjunction with the data interface provided by the module to write the corresponding codes to obtain data and draw a trajectory after the geographic location information is acquired;

S4. during the acquisition, it is necessary to initialize the GPS module (the corresponding codes should be used to ensure that GPS data can be acquired) and read the location information (latitude and longitude) provided by the GPS module, after reading, the location information read should be stored, and the corresponding trajectory drawing should be performed, during the drawing, the map API module should be used to create a map view and loop through the stored GPS location information, the current location point is plotted on a map (when there is a previous location point, a line segment connecting the current location point and the previous location point is drawn on the map). After acquiring the new GPS location information, the previously plotted trajectory on the map is cleared, a trajectory is updated on the map, the trajectory is redrawn according to the new location information; and the steps above are iterated through to achieve the effect of real-time updating; and

S5. in the process of acquiring the movement trajectories, the data storage and processing module and the microprocessor can transform the received and acquired information and its signals in real time, and transmit the transformed data to the display screen on the remote control body, the display screen adopts a dual-screen structure and the dual screens are electrically connected parts capable of being used in conjunction with each other, a small screen can display the speed during surfing in real time, a large screen can display the battery level and real-time gear during the surfing, and the display of the two screens can be switched by touch.

Compared with the prior art, the present disclosure has the following beneficial effects:

1. In the present disclosure, the arrangement of the processing mechanism, the protective mechanism and the connection assembly can effectively help the mounting and fixation of the control-type electrical components of the remote control body, and at the same time, upon completion of the mounting, the dual-screen design adopted by the display screen can effectively improve the functionality of the device during use, and make the use more convenient, allowing the user to directly observe the device and the operation of the device during user, and the mounting mechanism helps the user to mount and connect the action camera.

2. In the present disclosure, the design of the system can effectively enable the device to have a positioning function during use, and by the arrangement that the cell phone APP development tool contains an initialization GPS module, an acquisition GPS data module, a storage GPS data module, a trajectory drawing module, and a real-time update trajectory module, the movement trajectories of the user can be effectively recorded in real time when the device is used, and the safety and functionality of the device can be improved.

### BRIEF DESCRIPTION OF THE DRAWINGS

FIG. 1 is a structural perspective view of a wireless controller;

FIG. 2 is a bottom perspective view of a wireless controller;

FIG. 3 is an exploded view of a structure of a processing mechanism of a wireless controller;

FIG. 4 is a partial perspective view of a structure of a processing mechanism of a wireless controller;

FIG. 5 is an exploded view of a structure of a mounting mechanism of a wireless controller;

FIG. 6 is a partial perspective view of a structure of a connection assembly of a wireless controller; and

FIG. 7 is system schematic diagram of a wireless controller; and

FIG. 8 is system schematic diagram of a cell phone APP development tool of a wireless controller.

In the accompanying drawings: 100. remote control body; 101. processing mechanism; 101a. protective casing; 101b. encoder; 101c. processing unit; 101d. connecting member; 101e. locking member; 101f. fixed shell; 101g. display screen; 102. mounting mechanism; 102a. protective member; 102b. magnetic portion; 102c. control trigger; 102d. mounting groove; 102e. mounting position; 103. protective mechanism; 103a. handle; 103b. waterproof sleeve; 103c. connection assembly; 103c-1. sealing member; 103c-2. clamping plate; 103c-3. connection assembly; and 200. signal receiver.

### DETAILED DESCRIPTIONS OF THE EMBODIMENTS

In order to make the above objectives, features and advantages of the present disclosure more apparent and comprehensible, specific embodiments of the present disclosure will be described in detail below in conjunction with the accompanying drawings.

Many specific details are set forth in the following description for sufficient understanding of the present disclosure. However, the present disclosure may also be implemented in other manners different from that described herein. Similar popularizations may be made by persons skilled in the art without violating the connotations of the present disclosure. Therefore, the present disclosure is not limited by the specific embodiments disclosed below.

Reference in this specification to “one embodiment” or “an embodiment” means that a particular feature, structure, or characteristic that may be included in at least one implementation of the present disclosure. The appearance of the phrase “in one embodiment” in various places in this specification are not necessarily all referring to the same embodiment, nor are separate or alternative embodiments mutually exclusive of other embodiments.

### Embodiment 1

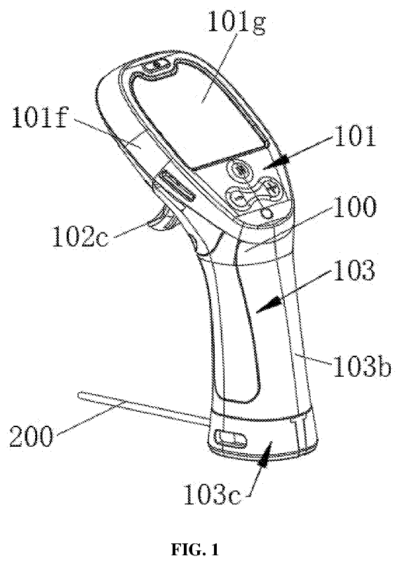

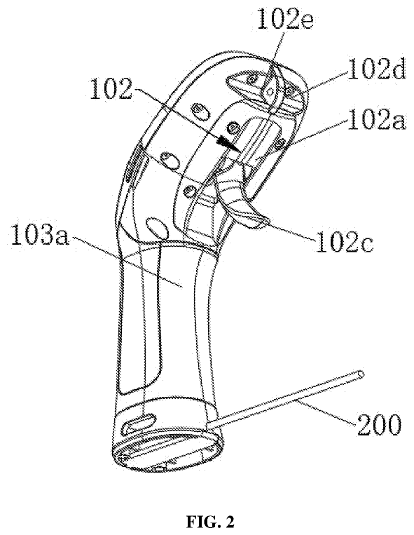

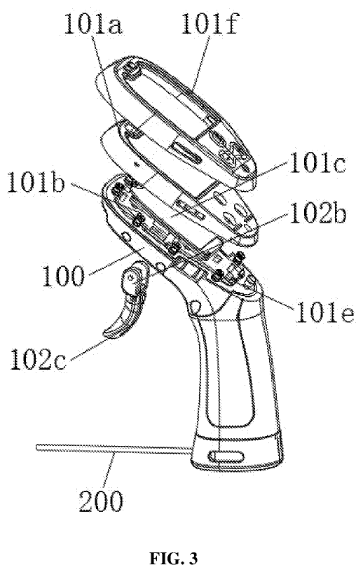

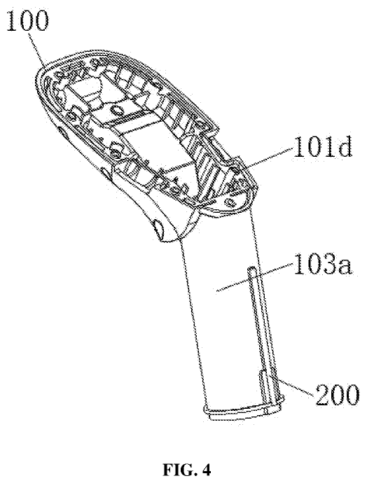

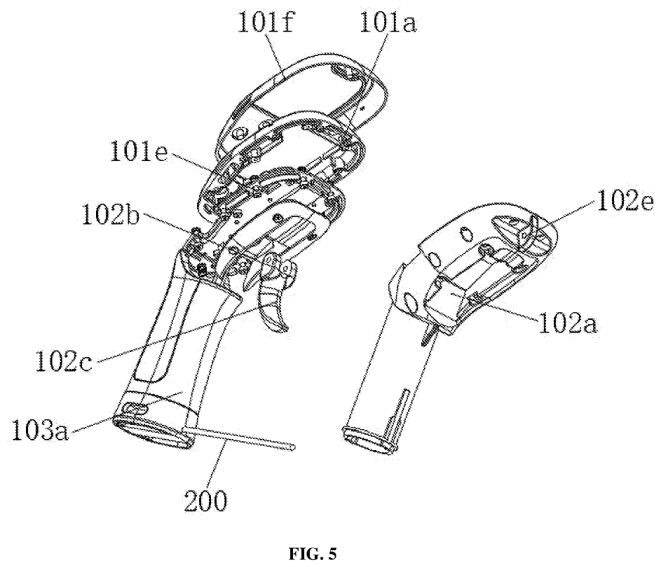

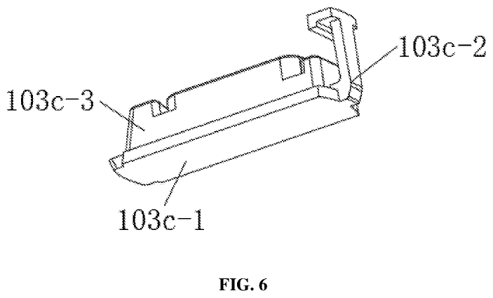

As shown in FIGS. 1-6, the first embodiment of the present disclosure is illustrated, which provides a wireless controller, including
a remote control body 100, including a processing mechanism 101 disposed at the top of the remote control body 100, a mounting mechanism 102 disposed on an outer side of the processing mechanism 101, and a protective mechanism 103 disposed on the bottom of the remote control body 100.

Specifically, the processing mechanism 101 includes a protective casing 101a disposed on an outer side of remote control body 100, an encoder 101b disposed on an inner side of the protective casing 101a, a processing unit 101c disposed on the surface of the encoder 101b, a connecting member 101d disposed on an outer side of the encoder 101b, a locking member 101e disposed on an outer side of the connecting member 101d, a fixed shell 101f disposed on an outer side of the protective casing 101a, and a display screen 101g disposed on an outer side of the processing unit 101c.

Further, the processing mechanism is arranged to facilitation the mounting and fixation by a user of the protective casing 101a, the encoder 101b, the processing unit 101c, the fixed shell 101f and the display screen 101g through the connecting member 101d and the locking member 101e, and the display screen 101g adopts a dual-screen design, which is more convenient to use.

Specifically, the dual-screen structure is arranged inside the display screen 101g, dual screens are electrically connected parts capable of being used in conjunction with each other, and the connecting member 101d, the protective casing 101a, the fixed shell 101f, and the locking member 101e are threaded parts capable of being used in conjunction with one another.

Specifically, the mounting mechanism 102 includes a protective member 102a disposed on the outer side of the remote control body 100, a magnetic portion 102b disposed on the inner cavity of the protective member 102a, a control trigger 102c disposed on an outer side of the magnetic portion 102b, a mounting groove 102d formed on an the outer side of the remote control body 100, and a mounting position 102e disposed inside the mounting groove 102d.

Further, the mounting groove 102d and the mounting position 102e contained inside the mounting mechanism 102 are convenient for the user to mount and connect an action camera.

Specifically, the protective mechanism 103 includes a handle 103a disposed at the bottom of the remote control body 100, a waterproof sleeve 103b disposed onto the surface of the handle 103a, and a connection assembly 103c disposed on an outer side of the handle 103a.

Further, the handle 103a facilitates handheld holding of the remote control body 100 by the user, and the waterproof sleeve 103b is provided to facilitate improvement of the waterproof effect of a device during use.

Specifically, the connection assembly 103c further includes a sealing member 103c-1 disposed on an outer side of the handle 103a, a clamping plate 103c-2 disposed on one side of the sealing member 103c-1, and a connection block 103c-3 disposed inside the sealing member 103c-1.

Further, the arrangement of the connection assembly 103c facilitates mounting and fixation of a signal receiver 200.

When in use, the user uses the processing mechanism 101 to mount and fix the protective casing 101a, the encoder 101b, the processing unit 101c, the fixed shell 101f, and the display screen 101g through the connecting member 101d and the locking member 101e, and upon completion of the mounting, the user mounts the control trigger 102c by using the protective member 102a and the magnetic portion 102b provided inside the mounting mechanism 102, and the user can then selectively mount the action camera through the mounting groove 102d and the mounting position 102e. Upon completion of mounting the processing mechanism 101, the user can mount and fix the signal receiver 200 through the sealing member 103c-1, the clamping plate 103c-2, and the connecting block 103c-3 inside the connection assembly 103c, and the user can then put the waterproof sleeve 103b onto the surface of the handle 103a, and after then, the user can take the device and electrically control the surfboard in the process of surfing by holding the handle 103a.

In summary, the arrangement of the processing mechanism 101, the protective mechanism 103 and the connection assembly 103c can effectively help the mounting and fixation of the control-type electrical components of the remote control body 100, and at the same time, upon completion of the mounting, the dual-screen design adopted by the display screen 101g can effectively improve the functionality of the device during use, and make the use more convenient, allowing the user to directly observe the device and the operation of the device during user, and the mounting mechanism 102 helps the user to mount and connect the action camera.

### Embodiment 2

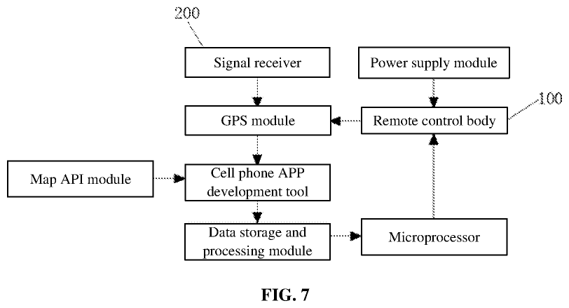

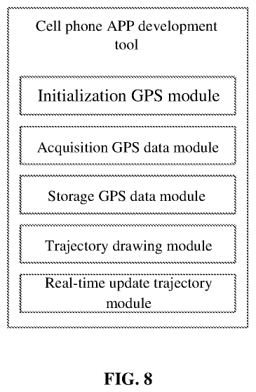

As shown in FIGS. 1-8, the second embodiment of the present disclosure is illustrated, which provides a wireless controller positioning system, and
a signal receiver 200, an output end of the signal receiver 200 is electrically connected to a GPS module, an input end of the remote control body 100 is electrically connected to a power supply module and a microprocessor, respectively, an output end of the GPS module is in communication connection with a cell phone APP development tool, an input end of the cell phone APP development tool is in communication connection with a map API module, and an output end of the cell phone APP development tool is electrically connected to a data storage and processing module.

Specifically, an output end of the data storage and processing module is electrically connected to an input end of the microprocessor, and an output end of the remote control body 100 is electrically connected to an input end of the GPS module.

Specifically, the cell phone APP development tool contains an initialization GPS module, an acquisition GPS data module, a storage GPS data module, a trajectory drawing module, and a real-time update trajectory module.

Specifically, the cell phone APP development tool needs to acquire GPS data when acquiring the movement trajectories:
including the initialization GPS module;
reading the location information provided by the GPS module;
storing the acquired location information; and
waiting for a certain period of time and continuing the next cycle;
drawing the trajectory:
creating a map view using a map API;
looping through the stored GPS location information;
plotting the current location point on a map, or when there is a previous location point, drawing a line segment connecting the current location point and the previous location point on the map;
clearing the previously plotted trajectory on the map after acquiring the new GPS location information;
updating a trajectory on the map and redrawing the trajectory according to the new location information; and iterating through the above steps to achieve the effect of real-time updating.

When in use, power is provided to the remote control body 100 through the power supply module during control. During the use of the remote control body 100, wireless signals needed by the device and the system are received by the signal receiver 200, geographic location information of the device is acquired through the GPS module upon receipt of the wireless signals, the cell phone APP development tool is used in conjunction with the data interface provided by the GPS module to write the corresponding codes to obtain GPS data and draw a trajectory after the geographic location information is acquired. During the acquisition, it is necessary to initialize the GPS module (the corresponding codes should be used to ensure that GPS data can be acquired) and read the location information (latitude and longitude) provided by the GPS module, after reading, the location information read should be stored, and the corresponding trajectory drawing should be performed, during the drawing, the map API module should be used to create a map view and loop through the stored GPS location information, the current location point is plotted on a map (when there is a previous location point, a line segment connecting the current location point and the previous location point is drawn on the map). After acquiring the new GPS location information, the previously plotted trajectory on the map is cleared, a trajectory is updated on the map, the trajectory is redrawn according to the new location information; and the steps above are iterated through to achieve the effect of real-time updating. In the process of acquiring the movement trajectories, the data storage and processing module and the microprocessor can transform the received and acquired information and its signals in real time, and transmit the transformed data to the display screen on the remote control body, the display screen adopts a dual-screen structure and the dual screens are electrically connected parts capable of being used in conjunction with each other, a small screen can display the speed during surfing in real time, a large screen can display the battery level and real-time gear during the surfing, and the display of the two screens can be switched by touch.

In summary, the design of the system can effectively enable the device to have a positioning function during use, and by the arrangement that the cell phone APP development tool contains an initialization GPS module, an acquisition GPS data module, a storage GPS data module, a trajectory drawing module, and a real-time update trajectory module, the movement trajectories of the user can be effectively recorded in real time when the device is used, and the safety and functionality of the device can be improved.

A wireless controller, its use method is as follows:

S1. the user uses the processing mechanism 101 to mount and fix the protective casing 101a, the encoder 101b, the processing unit 101c, the fixed shell 101f, and the display screen 101g through the connecting member 101d and the locking member 101e, and upon completion of the mounting, the user mounts the control trigger 102c by using the protective member 102a and the magnetic portion 102b provided inside the mounting mechanism 102, and the user can then selectively mount the action camera through the mounting groove 102d and the mounting position 102e;

S2. upon completion of mounting the processing mechanism 101, the user can mount and fix the signal receiver 200 through the sealing member 103c-1, the clamping plate 103c-2, and the connecting block 103c-3 inside the connection assembly 103c, and the user can then put the waterproof sleeve 103b onto the surface of the handle 103a, and after then, the user can take the device and electrically control the surfboard in the process of surfing by holding the handle 103a;

S3. power is provided to the remote control body 100 through the power supply module during control. During the use of the remote control body 100, wireless signals needed by the device and the system are received by the signal receiver 200, geographic location information of the device is acquired through the GPS module upon receipt of the wireless signals, the cell phone APP development tool is used in conjunction with the data interface provided by the GPS module to write the corresponding codes to obtain GPS data and draw a trajectory after the geographic location information is acquired;

S4. during the acquisition, it is necessary to initialize the GPS module (the corresponding codes should be used to ensure that GPS data can be acquired) and read the location information (latitude and longitude) provided by the GPS module, after reading, the location information read should be stored, and the corresponding trajectory drawing should be performed, during the drawing, the map API module should be used to create a map view and loop through the stored GPS location information, the current location point is plotted on a map (when there is a previous location point, a line segment connecting the current location point and the previous location point is drawn on the map); after acquiring the new GPS location information, the previously plotted trajectory on the map is cleared, a trajectory is updated on the map, the trajectory is redrawn according to the new location information; and the steps above are iterated through to achieve the effect of real-time updating; and

S5. in the process of acquiring the movement trajectories, the data storage and processing module and the microprocessor can transform the received and acquired information and its signals in real time, and transmit the transformed data to the display screen on the remote control body, the display screen adopts a dual-screen structure and the dual screens are electrically connected parts capable of being used in conjunction with each other, a small screen can display the speed during surfing in real time, a large screen can display the battery level and real-time gear during the surfing, and the display of the two screens can be switched by touch.

It is important to note that the construction and arrangement of the device as shown in the various exemplary embodiments is illustrative only. Although only a few embodiments have been described in detail in this disclosure, those skilled in the art who review this disclosure will readily appreciate that many modifications are possible (such as variations in sizes, dimensions, structures, shapes and proportions of the various elements, values of parameters, mounting arrangements, use of materials, colors, orientations, and the like) without materially departing from the novel teachings and advantages of the subject matter recited in the claims. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present disclosure. The order or sequence of any process or method steps may be varied or re-sequenced according to alternative embodiments. In the claims, any means-plus-function clause is intended to cover the structures described herein as performing the recited function and not only structural equivalents but also equivalent structures. Other substitutions, modifications, changes and omissions may be made in the design, operating conditions and arrangement of the exemplary embodiments without departing from the scope of the present disclosure. Therefore, the present disclosure is not limited to particular embodiments, but extends to a wide variety of modifications that still fall within the scope of the appended claims.

Additionally, in order to provide a concise description of these exemplary embodiments, not all features of an actual implementation may be described (that is, those features irrelevant to the best mode presently contemplated for carrying out the present disclosure, or those irrelevant to carrying out the present disclosure).

It should be understood that numerous implementation-specific decisions may be made during the development of any actual implementation, as in any engineering or design project. Such a development effort might be complex and time consuming, but would be a routine undertaking of design, manufacture and production without undue experimentation to those of ordinary skill having the benefit of the present disclosure.

It should be noted that the above embodiments are merely intended for describing the technical solutions of the present disclosure rather than limiting same. Although the present disclosure is described in detail with reference to the above embodiments, persons of ordinary skill in the art should understand that they may still make modifications or equivalent replacements to the technical solutions of the present disclosure without departing from the spirit and scope of the technical solutions of the present disclosure, which shall fall within the scope of the claims of the present disclosure.

What is claimed is:

1. A wireless controller, comprising:
a remote control body (100), comprising a processing mechanism (101) disposed at the top of the remote control body (100), a mounting mechanism (102) disposed on an outer side of the processing mechanism (101), and a protective mechanism (103) disposed on the bottom of the remote control body (100).

2. The wireless controller according to claim 1, wherein the processing mechanism (101) comprises a protective casing (101a) disposed on an outer side of remote control body (100), an encoder (101b) disposed on an inner side of the protective casing (101a), a processing unit (101c) disposed on the surface of the encoder (101b), a connecting member (101d) disposed on an outer side of the encoder (101b), a locking member (101e) disposed on an outer side of the connecting member (101d), a fixed shell (101f) disposed on an outer side of the protective casing (101a), and a display screen (101g) disposed on an outer side of the processing unit (101c).

3. The wireless controller according to claim 2, wherein the dual-screen structure is arranged inside the display screen (101g), dual screens are electrically connected parts capable of being used in conjunction with each other, and the connecting member (101d), the protective casing (101a), the fixed shell (101f), and the locking member (101e) are threaded parts capable of being used in conjunction with one another.

4. The wireless controller according to claim 1, wherein the mounting mechanism (102) comprises a protective member (102a) disposed on the outer side of remote control body (100), a magnetic portion (102b) disposed on the inner cavity of the protective member (102a), a control trigger (102c) disposed on an outer side of the magnetic portion (102b), a mounting groove (102d) formed on an the outer side of the remote control body (100), and a mounting position (102e) disposed inside the mounting groove (102d).

5. The wireless controller according to claim 1, wherein the protective mechanism (103) comprises a handle (103a) disposed at the bottom of the remote control body (100), a waterproof sleeve (103b) disposed onto the surface of the handle (103a), and a connection assembly (103c) disposed on an outer side of the handle (103a).

6. The wireless controller according to claim 5, wherein the connection assembly (103c) further comprises a sealing member (103c-1) disposed on an outer side of the handle (103a), a clamping plate (103c-2) disposed on one side of the sealing member (103c-1), and a connection block (103c-3) disposed inside the sealing member (103c-1).

7. A wireless controller positioning system, comprising the wireless controller according to claim 1, and
a signal receiver (200), an output end of the signal receiver (200) is electrically connected to a GPS module, an input end of the remote control body (100) is electrically connected to a power supply module and a microprocessor, respectively, an output end of the GPS module is in communication connection with a cell phone APP development tool, an input end of the cell phone APP development tool is in communication connection with a map API module, and an output end of the cell phone APP development tool is electrically connected to a data storage and processing module.

8. The wireless controller positioning system according to claim 7, wherein an output end of the data storage and processing module is electrically connected to an input end of the microprocessor, and an output end of the remote control body (100) is electrically connected to an input end of the GPS module.

9. The wireless controller positioning system according to claim 7, wherein the cell phone APP development tool contains an initialization GPS module, an acquisition GPS data module, a storage GPS data module, a trajectory drawing module, and a real-time update trajectory module.

10. The wireless controller positioning system according to claim 7, wherein the cell phone APP development tool needs to acquire GPS data when acquiring the movement trajectories:
comprising the initialization GPS module;
reading the location information provided by the GPS module;
storing the acquired location information; and
waiting for a certain period of time and continuing the next cycle;
drawing the trajectory:
creating a map view using a map API;
looping through the stored GPS location information;
plotting the current location point on a map, or when there is a previous location point, drawing a line segment connecting the current location point and the previous location point on the map;
clearing the previously plotted trajectory on the map after acquiring the new GPS location information;
updating a trajectory on the map and redrawing the trajectory according to the new location information; and
iterating through the above steps to achieve the effect of real-time updating.

11. A wireless controller, wherein the use method of the wireless controller is as follows:
S1. the user uses the processing mechanism (101) to mount and fix the protective casing (101a), the encoder (101b), the processing unit (101c), the fixed shell (101f), and the display screen (101g) through the connecting member (101d) and the locking member (101e), and upon completion of the mounting, the user mounts the control trigger (102c) by using the protective member (102a) and the magnetic portion (102b) provided inside the mounting mechanism (102), and the user can then selectively mount the action camera through the mounting groove (102d) and the mounting position (102e);
S2. upon completion of mounting the processing mechanism (101), the user can mount and fix the signal receiver (200) through the sealing member (103c-1), the clamping plate (103c-2), and the connecting block (103c-3) inside the connection assembly (103c), and the user can then put the waterproof sleeve (103b) onto the surface of the handle (103a), and after then, the user can take the device and electrically control the surfboard in the process of surfing by holding the handle (103a);
S3. power is provided to the remote control body (100) through the power supply module during control. During the use of the remote control body (100), wireless signals needed by the device and the system are received by the signal receiver (200), geographic location information of the device is acquired through the GPS module upon receipt of the wireless signals, the cell phone APP development tool is used in conjunction with the data interface provided by the GPS module to write the corresponding codes to obtain GPS data and draw a trajectory after the geographic location information is acquired;
S4. during the acquisition, it is necessary to initialize the GPS module (the corresponding codes should be used to ensure that GPS data can be acquired) and read the location information (latitude and longitude) provided by the GPS module, after reading, the location information read should be stored, and the corresponding trajectory drawing should be performed, during the drawing, the map API module should be used to create a map view and loop through the stored GPS location information, the current location point is plotted on a map (when there is a previous location point, a line segment connecting the current location point and the previous location point is drawn on the map); after acquiring the new GPS location information, the previously plotted trajectory on the map is cleared, a trajectory is updated on the map, the trajectory is redrawn according to the new location information; and the steps above are iterated through to achieve the effect of real-time updating; and
S5. in the process of acquiring the movement trajectories, the data storage and processing module and the microprocessor can transform the received and acquired information and its signals in real time, and transmit the transformed data to the display screen on the remote control body, the display screen adopts a dual-screen structure and the dual screens are electrically connected parts capable of being used in conjunction with each other, a small screen can display the speed during surfing in real time, a large screen can display the battery level and real-time gear during the surfing, and the display of the two screens can be switched by touch.
